(19) United States
(12) Patent Application Publication
(10) Pub. No.: US 2007/0085109 A1
(43) Pub. Date: Apr. 19, 2007

(54) Single element optical sensor

(75) Inventors: Yung-Jane Hsu, Hsinchu (TW); Yeu-Long Jiang, Hsinchu (TW)

Correspondence Address: BACON & THOMAS, PLLC, 625 SLATERS LANE, FOURTH FLOOR, ALEXANDRIA, VA, 22314, US

(73) Assignee: Frontend Analog and Digital Technology Corporation, Taipei (TW)

(21) Appl. No.: 11/249,459

(22) Filed: Oct. 14, 2005

(51) Int. Cl. H01L 27/148

(52) U.S. Cl. 257/233

(57) ABSTRACT

The single element optical sensor of this invention is a two-terminal element and comprises a light absorbing semiconductor layer, potential barrier materials positioned in said light absorbing layer and two electrodes connected to said light absorbing layer. Positions and chemical compositions of the potential barriers are adjusted according to wavebands of interests. Under different bias conditions photoelectric voltages with separated peaks are generated by the invented optical sensor, whereby color elements of an image may be obtained. Distinguish of light waves of selected wavebands may thus be achieved.

### FIELD OF THE INVENTION

The present invention relates to a single element optical sensor, especially to a two-terminal single-element optical sensor that is able to sense a plurality of light wave bands.

### BACKGROUND OF THE INVENTION

The optical sensor has been an element widely used in all kinds of computer equipments. The optical sensor is used to capture images to be input into a computer system and to convert the captured images into an electronic form in order to be processed by the computer system. A matrix comprising a plurality of optical sensors functions as retina of the computer. Such optical sensor array or matrix is widely used in all kinds of image input devices, such as image scanner, fax machine, copy machine, digital camera etc.

In the conventional art, optical sensors for particular waveband are made of semiconductor materials having particular bandgap, wherein photo-generated carriers in the depletion region of PN diode or PIN diode are driven by the electric field generated by reverse bias to drift to contact electrodes, so that photoelectric signals are generated.

Under such structures, the spectral response of one single PN diode or PIN diode will have only one peak. If optical signals of various wavebands shall be sensed, filters of selected colors shall be provided between light source and the optical sensors. The respective optical diodes will absorb light beams of selected wavebands and generate photoelectric signals to represent light elements of respective color. As a result, when light elements of the three primary colors shall be captured, three independent sets of optical sensor arrays or matrices shall be used, in combination respectively with filters of the three primary colors. Light elements of respective color are sensed separately and are then combined using a circuit or software. In such conventional art, the optical sensor device has a relatively larger area or size and its manufacture process is relatively complicated.

U.S. Pat. No. 6,034,407 disclosed a multi-spectral planar photodiode detector, wherein a plurality of optical sensing diodes is aligned on the same plan and signals generated therefrom are output from respective electrodes. The potential barriers between different photodiodes are separated.

U.S. Pat. No. 6,534,783 disclosed a stacked multiple quantum well superlattice infrared detector, wherein a plurality of optical sensing diodes is stacked to form a multi-color photo sensor, so to detect light waves in varies wavebands within the spectrum of infrared.

U.S. published patent application No. 2004-140,564 disclosed a CMOS image sensor, wherein a plurality of optical sensing diodes is stacked to form a multi-color photo sensor. The invention was able to detect visual light.

Different from the above-mentioned traditional technology, it is also possible to prepare a multi-color photo sensor by using one single two-terminal device. As single element, such multi-color optical sensor is helpful to reduce the size of the optical sensing device and simplify its manufacture process. Intensive studies and researches are made by scientists in this field. Most published technologies in the single element, multi-color optical sensor related to a stack of a plurality of intrinsic semiconductor layers (i-layers). Taking an optical sensor for the three primary colors as an example, it is possible to realize such sensor with an NIPIIN structure or an NIIIP structure, where N denotes an n-type semiconductor layer and P denotes a p-type semiconductor layer.

The operation of an optical sensor with the NIPIIN structure is as follows: Incident light beam enters into the optical sensor from the front N side. If a voltage is applied to generate a reverse bias in the front NIP diode, a corresponding forward bias will be generated at the rear PIIN diode. At this moment, the blue light is absorbed. On the other hand, if the voltage is applied to generate a forward bias in the front NIP diode, a corresponding reverse bias will be generated at the rear PIIN diode. Green light or red light can thus be detected. Furthermore, the μτ values (μ represents the mobility of carriers and τ stands for the lifetime of carriers) of the two i-layers in the PIIN diode may be adjusted in order to separate the green elements and the red elements of the detected signals. When the reverse bias is small, the i-layer adjacent to the P layer is first depleted to detect green elements. When the reverse bias is increased, the other i-layer is depleted to include the red elements. The difference between the detected singles at the smaller bias and that of the greater bias represents detected signals of red elements. As to the NIIIP structure, similar operations may be applied to identify color elements belonging to different wavebands.

A PININIP structure two-terminal device was also disclosed. Under such a structure, different biases are applied to deplete respective i-layers to distinguish color elements in detected signals.

Some modifications and improvements based on the above single element structure have been proposed in the past. Although the known single element structure optical sensor provides the function of distinguishing color elements of detected signals, it is still difficult to commercialize optical sensors of such single element structure. Problems rest in such structure include that with the modification of material property, the differences in the distribution of electric field in respective i-layers were not sufficient to efficiently distinguish respective color elements and that the manufacture processes were complicated.

U.S. Pat. No. 6,049,116 discloses a two-color infrared detector using a three-terminal NPN structure to distinguish two wavebands in the scope of infrared. This invention used two layers of HgCdTe material to detect optical waves of two different wavebands. A potential barrier is used to separate the two bands. However, this invention can only be applied to detect infrared lights. In addition, as three terminals are used, the infrared detector is more difficult to operate and the corresponding circuitry occupies larger area.

It is thus necessary to provide a single element, multi-color optical sensor whereby only one two-terminal element is used to detect light waves of a plurality of wavebands.

It is also necessary to provide a single element, multi-color optical sensor wherein visual light belonging to different wavebands may be easily distinguished.

### OBJECTIVES OF THE INVENTION

This is thus an objective of this invention to provide a novel single element multi-color optical sensor.

Another objective of this invention is to provide a single element optical sensor that can distinguish light elements of different wavebands.

Another objective of this invention is to provide a single element optical sensor that is able to detect visual colors.

Another objective of this invention is to provide an optical device comprising the above optical sensors.

### SUMMARY OF THE INVENTION

According to this invention, a single element optical sensor is provided. The invented optical sensor is a two-terminal element comprising semiconductor material. By using the technology of adjusting the bandgap of semiconductor material, suitable potential barriers are buried into the light absorbing layer of the two-terminal optical sensor. Photo-generated carriers by different lights would correspond to different collection efficiency under different biases and, thus, photoelectric signals will be generated in response to light waves of respective wavebands. Distinguishing light waves of selected wavebands may thus be achieved.

The single element optical sensor of this invention comprises a light absorbing layer, potential barrier materials positioned in said light absorbing layer and two electrodes connected to said light absorbing layer. Positions and chemical compositions of the potential barriers are adjusted according to wavebands in which color signals are to be detected. Under different bias conditions, photoelectric signals with separated spectral peaks are generated by the invented optical sensor, whereby color elements of an image may be obtained.

These and other objectives and advantages of this invention may be clearly understood from the detailed description by referring to the following drawings.

### BRIEF DESCRIPTION OF THE DRAWINGS

FIG. 1 shows the structure of a single element, two-waveband optical sensor of this invention

FIG. 2 shows the energy band diagram of the single element optical sensor of this invention, when a smaller bias is supplied.

FIG. 3 shows the photoelectric signals obtained under smaller and greater biases from the optical sensor of FIG. 1.

FIG. 4 shows the structure of a double barrier, three band optical sensor of this invention.

FIG. 5 shows the circuit diagram of an optical sensing device including the single element optical sensor of this invention.

FIG. 6 shows the circuit diagram of another optical sensing device employing the optical sensor of this invention.

### DETAILED DESCRIPTION OF THE INVENTION

The followings are descriptions to the structure, fabrication and application of the single element optical sensor of this invention. It shall be noted that detailed descriptions to the embodiments of this invention are only for purpose of illustration. Those skilled in the art may realize any modification or derivation from the detailed description. These modifications or derivations, however, shall belong to the scope of the present invention.

Although it is not intended to limit the scope of this invention, the inventor has found that, when suitable potential barriers are introduced into the transmission path of photo-generated currents in the light absorbing layer of a semiconductor optical sensor, and the bandgap of the semiconductor material is locally adjusted in a proper manner, the optical sensor may generate photoelectric currents with divided peaks in the spectrum, in response to different supplied biases. The optical sensor may thus detect light waves of varies wavebands. The present invention thus provides a method to design and adjust the structure of optical sensors, so that spectral responses of the optical sensors will include a plurality of relatively narrower peaks, which peaks may vary in response to the given bias conditions. Effective distinguish of color elements in an image is thus achieved. The present invention provides a single element optical sensor that is able to detect visual light waves of a plurality of wavebands.

Semiconductor material that can be used in the optical sensor of this invention includes all kinds of light absorbing semiconductors, such as semiconductor materials comprising the Group IV elements such as silicon, silicon-carbon, silicon-germanium etc. and their compositions, semiconductor materials comprising Groups III-V elements such as GaAs, InP etc, and semiconductor materials comprising of elements from Groups II-VI such as CdTe, HgCdTe, ZnSe etc.

In the structure of the invented optical sensor, potential barriers introduced into the light absorbing layer may be a single barrier structure, a double barrier structure, a multiple barrier structure etc., as long as light absorbing peaks generated by the optical sensor may be easily divided.

Electrodes to be used in the invented optical sensor may be prepared from any applicable electrode material. Suited material includes metal, metalized materials, or other highly conductive materials. The electrodes are connected to the two terminals of the light absorbing semiconductor layer or their adjacent areas, with no special limitations, as long as needed bias may be supplied to the light absorbing layer and photoelectric currents may be output from the light absorbing layer. If one electrode is positioned at the light incident terminal of the light absorbing layer, the electrode is preferably a transparent material. For example, ITO (Indium Tin Oxide) is a preferable material for such an electrode.

The optical sensor of this invention is not limited to any particular size. In principle, size of the optical sensor may be determined according to actual applications. To detect light waves of one waveband, the optical sensor may be in the size of several millimeters, so that sufficient power of signals may be obtained. To detect images, size of the optical sensor may be several micrometers, so that sufficient resolution of the detected image may be obtained.

It is possible to apply other layers of material, such as protection layer, anti-reflection layer etc., to the optical sensor of this invention. Taking the optical sensor made from silicon-based material for example, it is recommended to add silicon oxides such as SiO2 or silicon nitrides such as Si₃N₄ as material for the light incident surface. If the optical sensor is not silicon based, a glass substrate may be prepared and the optical sensor is prepared on the substrate. The glass substrate does not only function as transparent light incident surface of the optical sensor, but also facilities deposition of other layers of material onto it. The additional layers may be selectively used, as long as light detection effects are not reduced, size of the optical sensor is not unreasonably increased, wire connections are not hindered and processing of the output signals is not jeopardized.

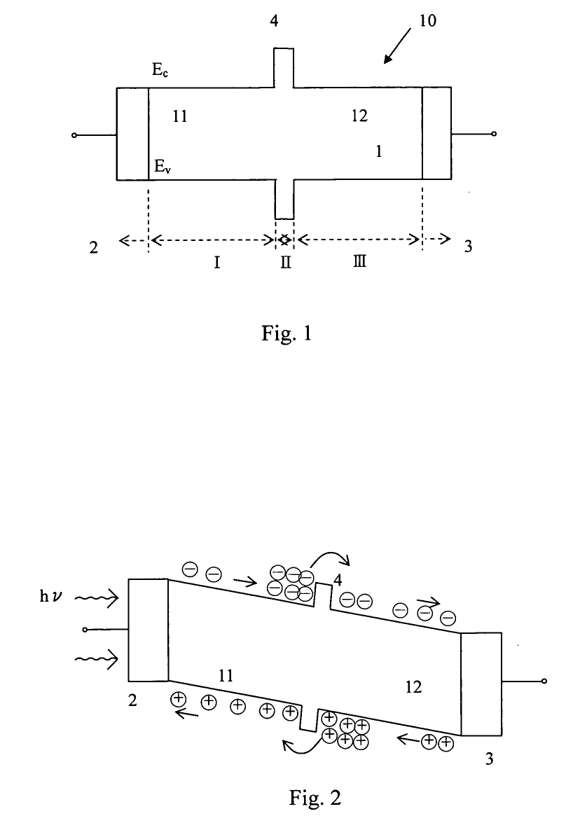

FIG. 1 shows the structure of the single element, two-waveband optical sensor of this invention. In this figure, shown is a single element optical sensor with one single potential barrier. As shown in this figure, the single element optical sensor is a two-terminal optical sensor 10 comprising a light absorbing semiconductor layer 1, two electrodes 2, 3 and a potential barrier 4 positioned in the light absorbing layer. In the shown structure, both electrodes 2, 3 position at the two terminals of the light absorbing layer 1. As a result, at least the first electrode 2 shall be transparent to the incident light.

The semiconductor layer 1 is a light absorbing layer. In general this layer is not doped with impurities so that light detecting efficiency may be increased. The light absorbing layer is divided into two detecting regions, i.e., the first detecting region 11 and the second detecting region 12, by the potential barrier 4. As shown in this figure, the bandgaps of these two detecting regions are set to be identical and the potential barrier has a greater bandgap.

The minimum detectable photon energy that can be detected by this optical sensor is determined by the magnitude of the bandgaps of the detecting regions 11, 12. The bandgap of the potential barrier 4 in turn determines the values of the potential barriers experienced by the electrons in the conduction band and the holes in the valence band. When a bias is applied to the two-terminal element 10, incident lights may thus be detected.

FIG. 2 shows the energy band diagram of the single element optical sensor of FIG. 1, when a smaller bias is supplied. As those skilled in the art may see from this figure, when light beam enters into a light absorbing material layer, its power will decay in a manner of exponential function. Light waves of different wave lengths have different decay indices. For shorter wave lengths, their absorption depths are also short, whereby most photons are absorbed at the surface of the absorbing layer and can not enter the deeper regions of the layer. On the other hand, longer wave lengths decay gradually along with depth of the layer and thus can reach deeper regions of the layer. Suppose light beams enter the light absorbing layer 1 from the transparent electrode 2, shorter wave lengths are absorbed in the first detecting region 11 and a substantial amount of longer wave lengths may reach the second detecting region 12 and are absorbed therein. As the potential barrier region 4 is always narrow and has greater bandgap, it will not constitute barrier for the light path.

The majority of carriers generated in the first detecting region 11 is induced by the shorter wave lengths. The majority of carriers generated in the second detecting region 12 is induced by the longer wave lengths. Under a relatively small bias, the photo-generated electrons in region 11 will be hindered by the potential barrier 4 and can not reach the second electrode 3. Moreover, these photo-generated electrons may be recombined by the holes that moves with a slow speed and thus disappear. On the other hand, photo-generated electrons in the second detecting region 12 can easily reach the second electrode 3. As a result, under a smaller bias, photoelectric signals generated by the optical sensor 10 are contributed by color elements of longer wave lengths.

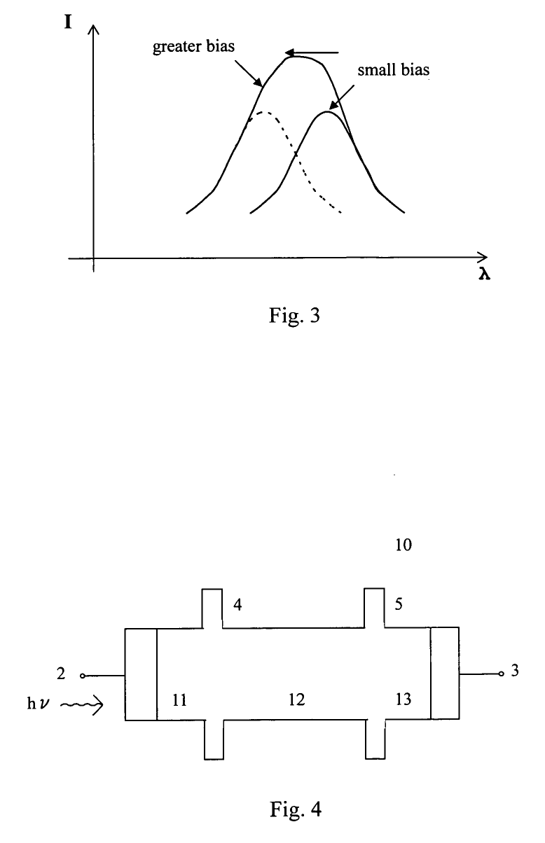

When the bias is increased to a level where photo-generated electrons in the first detecting region 11 have enough energy to overcome the potential barrier 4, they will reach the second detecting region 12 and the second electrode 3. Under such a bias condition, photoelectric signals generated by the optical sensor 10 are contributed jointly by color elements of longer and shorter wave lengths. Subtracting signals obtained under smaller bias from signals obtained under greater bias, signals contributed by shorter wave lengths may be obtained. The optical sensor can thus distinguish lights of two wavebands. FIG. 3 shows the photoelectric signals obtained under smaller and greater biases from the optical sensor of FIG. 1. As shown in this figure, by adjusting widths of the first detecting region 11 and the second detecting region 12, size and waveform of detectable light waves in the spectrum may be determined.

The single element, single potential barrier and two waveband optical sensor as described above distinguishes different wavebands by using different bias values under the same bias polarity. It is also possible to use small biases of different polarities to distinguish detected wavebands. For example, in the structure as shown in FIG. 2, applying a small bias with polarity as shown in FIG. 2 (where electrode 2 is negative to electrode 3), color elements of longer wave lengths may be detected. Then applying a small bias with reverse polarity (where electrode 3 is negative to electrode 2), color elements of shorter wave lengths may be detected.

Based on the above discussion, a three band optical sensor may be prepared by properly using the potential barriers. FIG. 4 shows the structure of a double-barrier, three-band optical sensor of this invention. In this figure, elements that are the same as those of FIG. 1 are labeled with the same numbers. As shown in this figure, the single-element, three-waveband optical sensor 10 comprises: a light absorbing semiconductor layer 1, two electrodes 2, 3 positioned at both terminals of the light absorbing layer 1 and two potential barriers 4, 5 positioned in the light absorbing layer 1. The potential barriers 4, 5 divide the light absorbing layer 1 into 3 detecting regions 11, 12 and 13.

The shorter, middle and longer wave lengths of the incident light are absorbed by the first detecting region 11, the second detecting region 12 and the third detecting region 13, respectively. When using the optical sensor of FIG. 4 to detect three wavebands, the potential structure of the optical sensor may be declined to the left side of this figure first. In other words, a small bias is applied so that the electronic potential at the first electrode 2 is made lower than that of the second electrode 3. At this moment, photo-generated current output by the optical sensor is in major contributed by the short wave lengths as they are absorbed by the first detecting region 11. When a reverse small bias is applied to make the potential structure to decline to the right side of the figure, photo-generated current output of the optical sensor is contributed by the longer wave lengths as they are absorbed by the third detecting region 13. Then a greater reverse bias is applied. At this moment, the photo-generated current output of the optical sensor is contributed by the longer, middle and shorter wave lengths. By subtracting from the obtained signals by those obtained previously, signals representing detected middle wave lengths may be obtained. As a result, optical signals of three wavebands may be easily obtained. As described above, by adjusting the widths of the first detecting region 11, the second detecting region 12 and the third detecting region 13, the spectral responses of the optical sensor may be adjusted. Successful detecting of light waves of selected wavebands may be realized.

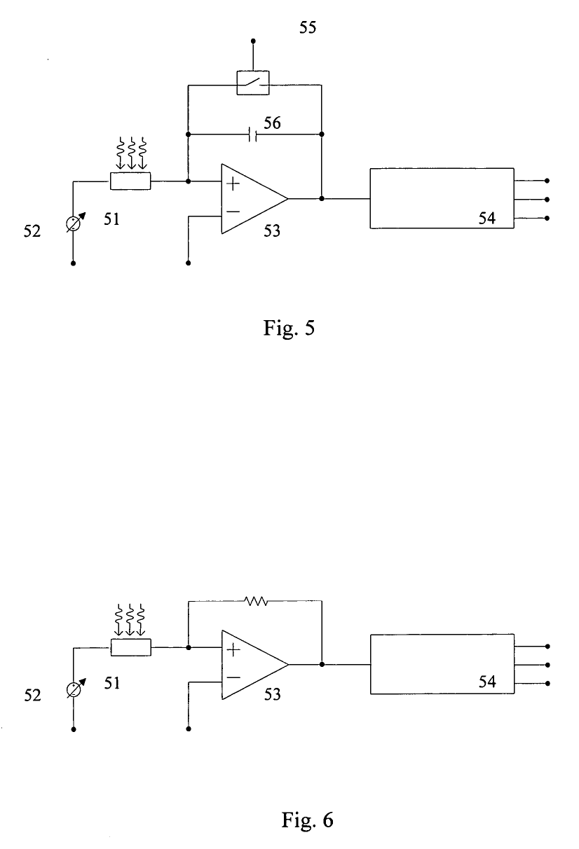

The single element optical sensor of this invention may be assembled with applicable wires and circuits to output detecting signals for selected wavebands. FIG. 5 shows the circuit diagram of an optical sensing device including the single element optical sensor of this invention. As shown in this figure, the optical sensing device comprises an optical sensor 51 to detect incident light waves, a variable power source 52 to supply a variable bias to the optical sensor 51, a comparator 53 with a reference voltage Vref and output of the optical sensor 51 as its inputs, capacitor C connected in parallel with the comparator 53 to convert output of the optical sensor 51 into voltage, and signal processing unit 54 to control output bias of the variable power source 52 and the output current of the optical sensor 51. The output of the signal processing unit 54 are R, G, B outputs representing detected signals in three respective wavebands. The device further comprises a reset 55 and a switch 56, to clear residual potential in capacitor C before operation of the optical sensing device.

FIG. 6 shows the circuit diagram of another optical sensing device employing the optical sensor of this invention. In this figure, elements that are the same as those in FIG. 5 are labeled with the same numbers. As shown in this figure, a resistor R is used to replace the capacitor C of FIG. 5, to convert the output current of the optical sensor 51 into voltage.

As the present invention has been shown and described with reference to preferred embodiments thereof, those skilled in the art will recognize that the above and other changes may be made therein without departing from the spirit and scope of the invention.

What is claimed is:

1. A single element optical sensor, comprising: a light absorbing semiconductor layer, potential barrier region positioned in said light absorbing layer and two electrodes connected to said light absorbing layer.

2. The single element optical sensor according to claim 1, wherein said potential barrier region is positioned at a distance from a light incident surface of said light absorbing layer, such that when different bias is applied to said optical sensor and an incident light is applied to said light incident surface, said optical sensor generates different photo-generated currents in response to different wavelength elements of said incident light.

3. The single element optical sensor according to claim 1, wherein the compositions of material for said potential barrier region and the detecting regions are adjusted such that when different bias is applied to said optical sensor and an incident light is applied to said light incident surface, said optical sensor generates different photo-generated currents in response to different wavelength elements of said incident light.

4. The single element optical sensor according to claim 1, wherein distance between said potential barrier region and a light incident surface of said light absorbing layer and composition of material for said potential barrier region are adjusted such that when different bias is applied to said optical sensor and an incident light is applied to said light incident surface, said optical sensor generates different photo-generated currents in response to different wavelength elements of said incident light.

5. The single element optical sensor according to claim 1, wherein said light absorbing semiconductor layer comprises at least one element selected from Group IV, Groups III-V or Groups II-V or their compounds.

6. The single element optical sensor according to claim 2, wherein said light absorbing semiconductor layer comprises at least one element selected from Group IV, Groups III-V or Groups II-V or their compounds.

7. The single element optical sensor according to claim 3, wherein said light absorbing semiconductor layer comprises at least one element selected from Group IV, Groups III-V or Groups II-V or their compounds.

8. The single element optical sensor according to claim 4, wherein said light absorbing semiconductor layer comprises at least one element selected from Group IV, Groups III-V or Groups II-V or their compounds.

9. The single element optical sensor according to claim 5, wherein said light absorbing semiconductor layer comprises at least one element selected from the group consisted of silicon, silicon-carbon, silicon-germanium and their compositions.

10. The single element optical sensor according to claim 6, wherein said light absorbing semiconductor layer comprises at least one element selected from the group consisted of silicon, silicon-carbon, silicon-germanium and their compositions.

11. The single element optical sensor according to claim 7, wherein said light absorbing semiconductor layer comprises at least one element selected from the group consisted of silicon, silicon-carbon, silicon-germanium and their compositions.

12. The single element optical sensor according to claim 8, wherein said light absorbing semiconductor layer comprises at least one element selected from the group consisted of silicon, silicon-carbon, silicon-germanium and their compositions.

13. The single element optical sensor according to claim 5, wherein said light absorbing semiconductor layer comprises at least one element selected from the group consisted of GaAs, InP, CdTe, HgCdTe, ZnSe and their compositions.

14. The single element optical sensor according to claim 6, wherein said light absorbing semiconductor layer comprises at least one element selected from the group consisted of GaAs, InP, CdTe, HgCdTe, ZnSe and their compositions.

15. The single element optical sensor according to claim 7, wherein said light absorbing semiconductor layer comprises at least one element selected from the group consisted of GaAs, InP, CdTe, HgCdTe, ZnSe and their compositions.

16. The single element optical sensor according to claim 8, wherein said light absorbing semiconductor layer comprises at least one element selected from the group consisted of GaAs, InP, CdTe, HgCdTe, ZnSe and their compositions.

17. The single element optical sensor according to claim 1, comprising at least 2 potential barrier regions.

18. The single element optical sensor according to claim 2, comprising at least 2 potential barrier regions.

19. The single element optical sensor according to claim 3, comprising at least 2 potential barrier regions.

20. The single element optical sensor according to claim 4, comprising at least 2 potential barrier regions.

21. The single element optical sensor according to claim 1, wherein one electrode is transparent and is positioned at a light incident terminal of said light absorbing semiconductor layer.

22. The single element optical sensor according to claim 17, wherein one electrode is transparent and is positioned at a light incident terminal of said light absorbing semiconductor layer.

23. An optical sensing device, comprising:
an optical sensor to detect incident light and to generate photo-generated currents in response to light wave elements in particular wavebands of said incident light;
a variable power source to supply a variable bias to said optical sensor;
a comparator to compare a reference voltage and output of said optical sensor;
a current to voltage converter to convert output current of said optical sensor into voltage; and
a signal processing unit to control output bias of said variable power source and output of said optical sensor;
wherein said optical sensor comprises: a light absorbing semiconductor layer, potential barrier region positioned in said light absorbing layer and two electrodes connected to said light absorbing layer.

24. The optical sensing device according to claim 23, wherein said potential barrier region is positioned at a distance from a light incident surface of said light absorbing layer, such that when different bias is applied to said optical sensor and an incident light is applied to said light incident surface, said optical sensor generates different photo-generated currents in response to different wavelength elements of said incident light.

25. The optical sensing device according to claim 23, wherein composition of material for said potential barrier region is adjusted such that when different bias is applied to said optical sensor and an incident light is applied to said light incident surface, said optical sensor generates different photo-generated currents in response to different wavelength elements of said incident light.

26. The optical sensing device according to claim 23, wherein distance between said potential barrier region and a light incident surface of said light absorbing layer and composition of material for said potential barrier region are adjusted such that when different bias is applied to said optical sensor and an incident light is applied to said light incident surface, said optical sensor generates different photo-generated currents in response to different wavelength elements of said incident light.

27. The optical sensing device according to claim 23, wherein said light absorbing semiconductor layer comprises at least one element selected from Group IV, Groups III-V or Groups II-V or their compounds.

28. The optical sensing device according to claim 24, wherein said light absorbing semiconductor layer comprises at least one element selected from Group IV, Groups III-V or Groups II-V or their compounds.

29. The optical sensing device according to claim 25, wherein said light absorbing semiconductor layer comprises at least one element selected from Group IV, Groups III-V or Groups II-V or their compounds.

30. The optical sensing device according to claim 26, wherein said light absorbing semiconductor layer comprises at least one element selected from Group IV, Groups III-V or Groups II-V or their compounds.

31. The optical sensing device according to claim 27, wherein said light absorbing semiconductor layer comprises at least one element selected from the group consisted of silicon, silicon-carbon, silicon-germanium and their compositions.

32. The optical sensing device according to claim 28, wherein said light absorbing semiconductor layer comprises at least one element selected from the group consisted of silicon, silicon-carbon, silicon-germanium and their compositions.

33. The optical sensing device according to claim 29, wherein said light absorbing semiconductor layer comprises at least one element selected from the group consisted of silicon, silicon-carbon, silicon-germanium and their compositions.

34. The optical sensing device according to claim 30, wherein said light absorbing semiconductor layer comprises at least one element selected from the group consisted of silicon, silicon-carbon, silicon-germanium and their compositions.

35. The optical sensing device according to claim 27, wherein said light absorbing semiconductor layer comprises at least one element selected from the group consisted of GaAs, InP, CdTe, HgCdTe, ZnSe and their compositions.

36. The optical sensing device according to claim 28, wherein said light absorbing semiconductor layer comprises at least one element selected from the group consisted of GaAs, InP, CdTe, HgCdTe, ZnSe and their compositions.

37. The optical sensing device according to claim 29, wherein said light absorbing semiconductor layer comprises at least one element selected from the group consisted of GaAs, InP, CdTe, HgCdTe, ZnSe and their compositions.

38. The optical sensing device according to claim 30, wherein said light absorbing semiconductor layer comprises at least one element selected from the group consisted of GaAs, InP, CdTe, HgCdTe, ZnSe and their compositions.

39. The optical sensing device according to claim 23, comprising at least 2 potential barrier regions.

40. The optical sensing device according to claim 24, comprising at least 2 potential barrier regions.

41. The optical sensing device according to claim 25, comprising at least 2 potential barrier regions.

42. The optical sensing device according to claim 26, comprising at least 2 potential barrier regions.

43. The optical sensing device according to claim 23, wherein one electrode is transparent and is positioned at a light incident terminal of said light absorbing semiconductor layer.
